(19) United States
(12) Patent Application Publication
(10) Pub. No.: US 2013/0153008 A1
(43) Pub. Date: Jun. 20, 2013

(54) PHOTOVOLTAIC MODULE

(71) Applicant: E I Du Pont De Nemours and Company, Wilmington, DE (US)

(72) Inventor: Angelique Genevieve Lucie Garreau-Iles, Challonges (FR)

(73) Assignee: E I DU PONT DE NEMOURS AND COMPANY, Wilmington, DE (US)

(21) Appl. No.: 13/713,095

(22) Filed: Dec. 13, 2012

Related U.S. Application Data
(60) Provisional application No. 61/570,964, filed on Dec. 15, 2011.

(51) Int. Cl. H01L 31/0203; H01L 31/18

(52) U.S. Cl. CPC H01L 31/0203; H01L 31/18
USPC 136/251; 136/259; 438/66

(57) ABSTRACT

A photovoltaic module comprising, in this order, a front sheet, a front encapsulant layer having a total area (B) consisting of one or more in-plane elements, one or more photoactive cells, a back encapsulant layer having an area (A), and a back sheet, wherein the front encapsulant layer having the total area (B) covers the area defined by the one or more photovoltaic cells and wherein the total area (B) of the front encapsulant layer is smaller than the area (A) of the back encapsulant layer, and wherein the contours of the one or more in-plane elements of the front encapsulant layer and the contour of the back encapsulant layer do not intersect.

### FIELD OF THE INVENTION

The present invention relates to photovoltaic modules and the manufacture thereof.

### BACKGROUND OF THE INVENTION

Photovoltaic cells, sometimes called solar cells or photoactive cells, can convert light, such as sunlight, into electrical energy that can be used for multiple applications.

In practice, a plurality of photovoltaic cells are electrically connected together in series or in parallel to form an array of photovoltaic cells which can be incorporated into a photovoltaic module.

In general, a module includes an array of photoactive cells that are connected in series by connecting the anode of one photovoltaic cell to the cathode of the next cell.

In most of today's photovoltaic modules, the photovoltaic cells that convert light into electrical energy are embedded, or encapsulated, in polymeric resins in order to protect the photovoltaic cells.

Besides forming a barrier layer that protects the photovoltaic cells against chemical stress and humidity and forming a “cushion” that mechanically protects the fragile photovoltaic cells against hail impact and other mechanical stress, the encapsulant layers also provide necessary electrical insulation to avoid short-circuits.

The encapsulant layer between the frontface of photovoltaic cells and the front sheet (usually glass) is called the front encapsulant layer, whereas the back encapsulant layer is the encapsulant layer situated between the photovoltaic cell and the back sheet.

When choosing a polymeric front encapsulant layer to be used in a photovoltaic module, a primary consideration is given to the transparency of the polymeric resin, that is, the ability of the resin to let through incident light. When the transparency of the polymeric resin is higher, more light can be converted into electrical energy by the photovoltaic cell.

Among polymeric encapsulants useful in the manufacture of photovoltaic modules, encapsulants based on partially neutralized copolymers of ethylene and (meth)acrylic acid, also called ionomers, are known for their excellent transparency and mechanical properties.

However, some ionomer-based encapsulants may suffer from weak adhesion to multiple materials used in photovoltaic module manufacture, including the front sheet.

This lack of sufficient adhesion to certain materials leads to premature delamination at the interface between the front sheet and the ionomer encapsulant, as the front sheet of the photovoltaic module expands and contracts because of thermal expansion during the lifetime of the module. The delamination problem most often occurs at the peripheral edges of the module, from which an initial delamination defect then spreads towards the center, as the module is exposed to temperature cycles and humidity throughout its lifetime.

Without wishing to be held to any theory, it is believed that the adhesive failure between the front encapsulant and the front sheet is exacerbated in the case where the front encapsulant has a relatively high modulus in the range of 200 to 400 MPa (when measured according to ASTM D5026 at a temperature of 23° C. and a relative humidity of 23%), which impedes the front encapsulant from following the thermal expansion of the front sheet.

It is possible to treat the front sheet with silane-based adhesion promoters which react with the material of the front encapsulant in order to increase the adhesion at the interface between the front encapsulant layer and the front sheet of the photovoltaic module, and thereby to reduce the incidence of the above described problems.

However, such treatments are time-consuming and add an additional step to the manufacturing process of the photovoltaic module, in addition to being economically disadvantageous.

Therefore, there exists a need to provide a photovoltaic module that does not suffer from the above-mentioned problems of delamination between the front encapsulant layer and the front sheet, and which at the same time can be manufactured at a reduced cost when compared to modern module assemblies, while benefiting from the excellent optical properties of certain front encapsulant resins, such as for example ionomers.

### SUMMARY OF THE INVENTION

The present invention provides for a photovoltaic module comprising, in this order, a front sheet, a front encapsulant layer having a total area (B) consisting of one or more in-plane elements, one or more photoactive cells, a back encapsulant layer having an area (A), and a back sheet, wherein the front encapsulant layer having the total area (B) covers the area defined by the one or more photovoltaic cells and, optionally, the area between the photoactive cells, wherein the total area (B) of the front encapsulant layer is smaller than the area (A) of the back encapsulant layer, and wherein the contours of the one or more in-plane elements of the front encapsulant layer and the contour of the back encapsulant layer do not intersect.

The present invention further provides for a process for the manufacture of a photovoltaic module comprising the steps of: (a) assembling a stack by placing at least one sheet of a back encapsulant having an area (A) on top of a back sheet to form a back encapsulant layer thereon, placing one or more photoactive cells on top of the at least one sheet of the back encapsulant, placing one or more sheets of a front encapsulant consisting of one or more in-plane elements on top of the one or more photoactive cells to form thereon a front encapsulant layer having a total area (B), placing a front sheet on top of the one or more front encapsulant sheets, and (b) consolidating the so assembled stack in a laminating device by heating the stack to a temperature of 100 to 180° C., subjecting the heated stack to a mechanical pressure in a direction perpendicular to the plane of the stack by forming a vacuum in the laminating device, cooling the stack to ambient temperature, and releasing the mechanical pressure by reestablishing atmospheric pressure in the laminating device, wherein the front encapsulant layer having the total area (B) covers the area defined by the one or more photovoltaic cells plus, optionally, the area between the photoactive cells, wherein the total area (B) of the front encapsulant layer formed is smaller than the area (A) of the back encapsulant layer, and wherein the contours of the one or more in-plane elements and the contour of the back encapsulant layer do not intersect.

### BRIEF DESCRIPTION OF THE DRAWINGS

FIG. 1 is an exploded perspective view of a prior art photovoltaic module.

FIG. 2 is an exploded perspective view of a photovoltaic module according to one embodiment.

FIG. 3 is an exploded perspective view of a photovoltaic module according to another embodiment.

### DETAILED DESCRIPTION

For the purpose of the present disclosure, the term “backface” denotes the surface of a photovoltaic cell in a photovoltaic module which faces away from incident light, i.e. which faces the back sheet.

For the purpose of the present disclosure, the term “frontface” denotes the surface of a photovoltaic cell in a photovoltaic module which faces towards incident light, i.e. which faces away from the back sheet and towards the front sheet.

For the purpose of the present disclosure, the term “light” means any type of electromagnetic radiation that can be converted into electric energy by a photovoltaic cell.

For the purpose of the present disclosure, the terms “photoactive” and “photovoltaic” may be used interchangeably and refer to the property of converting radiant energy (e.g., light) into electric energy.

For the purpose of the present disclosure, the terms “photovoltaic cell” or “photoactive cell” means an electronic device that can convert any type of electromagnetic radiation (e.g., light) into an electrical signal. A photovoltaic cell includes a photoactive material layer that may be an organic or inorganic semiconductor material that is capable of absorbing radiation and converting it into electrical energy. The terms “photovoltaic cell” or “photoactive cell” are used herein to include solar cells with any types of photoactive layers including crystalline silicon, amorphous silicon, cadmium telluride, and copper indium gallium selenide (GIGS) photoactive layers.

For the purpose of the present disclosure, the term “photovoltaic module” (also “module” for short) means any electronic device having at least one photovoltaic cell.

For the purpose of the present disclosure, the term “encapsulant layer” refers to a layer of material that is designed to protect the photoactive cells from degradation caused by chemical and/or mechanical damage.

For the purpose of the present disclosure, the term “front encapsulant layer” refers to an encapsulant layer that is located between the frontface of a photoactive cell and the front sheet of the module.

For the purpose of the present disclosure, the term “back encapsulant layer” refers to an encapsulant layer that is located between the backface of a photoactive cell and the back sheet of the module.

For the purpose of the present disclosure, the term “contour” refers to the outline, or the closed path formed by the border edge, of a component in a photovoltaic module, when viewed along an axis normal to the plane of the module.

For the purpose of the present disclosure, the term “intersection” refers to line-line intersection between at least two contours of components in a photovoltaic module, when viewed along an axis normal to the plane of the module. For the purpose of the present disclosure, the term “to intersect” refers to the presence, or occurrence, of at least one intersection.

The photovoltaic module according to the present invention comprises, in this order, a front sheet, a front encapsulant layer having a total area (B) consisting of one or more in-plane elements, one or more photoactive cells, a back encapsulant layer having an area (A), and a back sheet, wherein the front encapsulant layer having the total area (B) covers the area defined by the one or more photovoltaic cells and, optionally, the area between the photoactive cells, wherein the total area (B) of the front encapsulant layer is smaller than the area (A) of the back encapsulant layer, and wherein the contours of the one or more in-plane elements of the front encapsulant layer and the contour of the back encapsulant layer do not intersect.

In a preferred embodiment, the photovoltaic module according to the present invention comprises, in this order, a front sheet, a front encapsulant layer having a total area (B) consisting of one or more in-plane elements, one or more photoactive cells, a back encapsulant layer having an area (A), and a back sheet, wherein the front encapsulant layer having the total area (B) covers only the area defined by the one or more photovoltaic cells plus the area between the photoactive cells, wherein the total area (B) of the front encapsulant layer is smaller than the area (A) of the back encapsulant layer, and wherein the contours of the one or more in-plane elements of the front encapsulant layer and the contour of the back encapsulant layer do not intersect.

In a still more preferred embodiment, the photovoltaic module according to the present invention comprises, in this order, a front sheet, a front encapsulant layer having a total area (B) consisting of one or more in-plane elements, one or more photoactive cells, a back encapsulant layer having an area (A), and a back sheet, wherein the front encapsulant layer having the total area (B) covers only the area defined by the one or more photovoltaic cells, wherein the total area (B) of the front encapsulant layer is smaller than the area (A) of the back encapsulant layer, and wherein the contours of the one or more in-plane elements of the front encapsulant layer and the contour of the back encapsulant layer do not intersect.

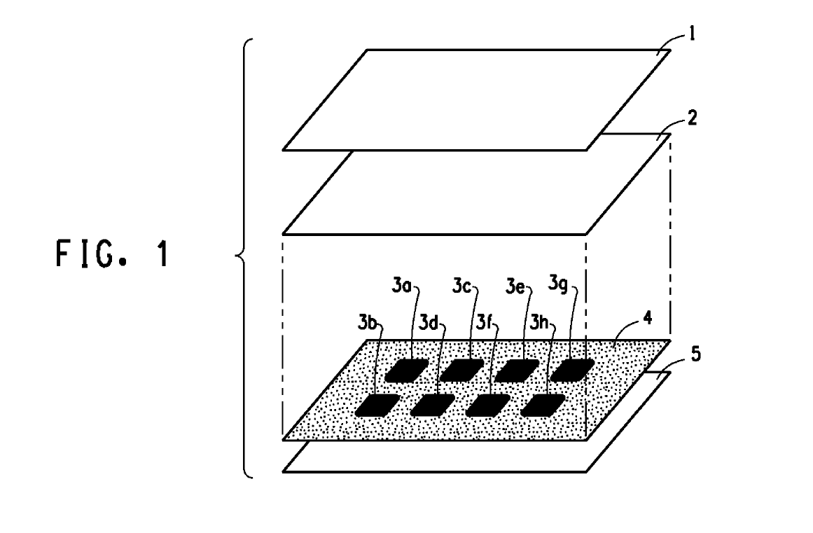

FIG. 1 depicts an exploded perspective view of a prior art photovoltaic module comprising a front sheet 1, a front encapsulant layer 2 having a total area (B), an array of 8 photoactive cells (3a-3h), a back encapsulant layer 4 and a back sheet 5, wherein the area (B) of the front encapsulant layer is equal to the area (A) of the back encapsulant layer and wherein the contour of the front encapsulant layer and the contour of the back encapsulant layer intersect and overlap so as to exactly superimpose.

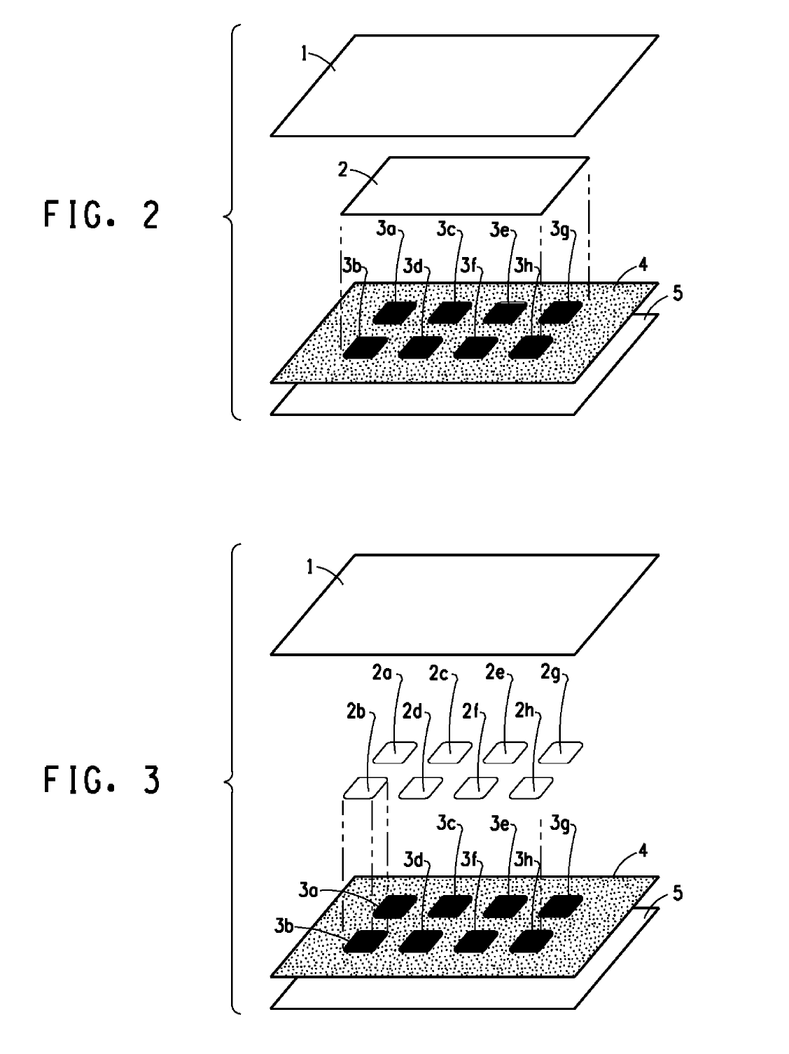

FIG. 2 depicts an exploded perspective view of a photovoltaic module comprising a front sheet 1, a front encapsulant layer 2 having a total area (B), an array of 8 photoactive cells (3a-3h), a back encapsulant layer 4 having an area (A) and a back sheet 5, wherein the front encapsulant layer having the total area (B) covers the area defined by the 8 photovoltaic cells and the area between the photoactive cells, wherein the total area (B) of the front encapsulant layer is smaller than the area (A) of the back encapsulant layer, and wherein the contours of front encapsulant layer and the contour of the back encapsulant layer do not intersect.

FIG. 3 depicts an exploded perspective view of a photovoltaic module comprising a front sheet 1, a front encapsulant layer 2 having a total area (B) and consisting of 8 in-plane elements (2a-2h), an array of 8 photoactive cells (3a-3h), a back encapsulant layer 4 having an area (A) and a back sheet 5, wherein the front encapsulant layer, consisting of 8 in-plane elements, and having a total area (B) covers only the area defined by the 8 photovoltaic cells, wherein the total area (B) of the front encapsulant layer is smaller than the area (A) of the back encapsulant layer, and wherein the contours of the 8 in-plane elements of the front encapsulant layer and the contour of the back encapsulant layer do not intersect.

The front sheet in the photovoltaic module according to the present invention may be any front sheet as is conventional in the art of photovoltaic modules, i.e. the front sheet may be formed from any light transmitting material, which may be rigid or flexible and the thickness of the front sheet may be in the range of, for example, 50 to 4000 μm, as is conventional for front sheets of photovoltaic modules.

The function of the front sheet is to provide a transparent protective layer that will allow incident light (e.g., sunlight) to reach the frontface of the photovoltaic cell.

In general, the front sheet material may be any material that provides protection against the elements for the module while also providing transparency to the incident light.

The front sheet may be made of a rigid material, such as a glass, polycarbonate, acrylate polymer such as polymethylmethacrylate (PMMA) material, or a more flexible material, such as a fluoropolymer like for example polyvinyl fluoride (PVF), a polyvinylidene fluoride (PVDF), an ethylene tetrafluorethylene (ETFE) polymer, a perfluoroalkoxy vinyl polymer (PFA), an FEP (fluorinated ethylene propylene) copolymer of tetrafluoroethylene (TFE) and hexafluoropropylene (HFP), or a combination thereof.

The front sheet may be a single layer of material, or may include more than one layer of the same or different materials. Preferably, the front sheet in the photovoltaic module according to the present invention has the same area (A) as the back encapsulant layer.

The photovoltaic module according to the present invention comprises a front encapsulant layer consisting of one or more in-plane elements.

The front encapsulant layer in the photovoltaic module according to the present invention may comprise any material as is conventional in the art of photovoltaic modules, i.e. the front encapsulant layer may comprise various transparent polymeric materials, and preferably comprises a polymeric material having a Young Modulus of from 200 to 400 MPa, preferably of from 250 to 350 MPa more preferably of from 280 to 320, when measured according to ASTM D5026 at a temperature of 23° C. at a relative humidity of 23%.

The thickness of the front encapsulant layer may be in the range of, for example, 100 to 2000 μm, preferably of from 200 to 1000 μm, as is conventional for front encapsulant layers in photovoltaic modules.

The front encapsulant layer of the photovoltaic module according to the present invention is located adjacent to and between the front sheet and the frontface of the one or more photovoltaic cells and forms a layer of front encapsulant that can consist of one or more in-plane (co-planar) elements. Stated alternatively, the front encapsulant layer may be present in the form of either a continuous layer consisting of one element, or an as an interrupted layer consisting of more than one in-plane element.

The front encapsulant layer is designed to encapsulate and further protect the frontface of the photoactive cells from environmental degradation and mechanical damage, but at the same time is required to have excellent transparency that allows a maximum of incident light to reach the frontface of the photoactive cells, and also bonds the one or more photoactive cells to the front sheet.

Preferably, the front encapsulant layer according to the present invention comprises at least a first ionomer, and preferably comprises a blend of a first ionomer and a second ionomer different from the first ionomer or a blend of a first ionomer and an non-neutralized copolymer of ethylene and (meth)acrylic acid.

As used herein, the term “ionomer” means and denotes a thermoplastic resin containing both covalent and ionic bonds derived from ethylene copolymers. In some embodiments, monomers formed by partial neutralization of ethylene-methacrylic acid copolymers or ethylene-acrylic acid copolymers with inorganic bases having cations of elements from Groups I, II, or III of the Periodic table, notably, sodium, aluminum, lithium, magnesium, and barium may be used, or transition metals such as zinc. The term “ionomer” and the resins identified thereby are well known in the art, as evidenced by Richard W. Rees, “Ionic Bonding In Thermoplastic Resins”, DuPont Innovation, 1971, 2(2), pp. 1-4, and Richard W. Rees, “Physical Properties And Structural Features Of Surlyn Ionomer Resins”, Polyelectrolytes, 1976, C, 177-197.

Ionomers useful in the front encapsulant layer of the module of the present invention may be chosen from ionomers obtained by the copolymerization of ethylene and an ethylenically unsaturated, C3 to C8 carboxylic acid, such as for example methacrylic acid or acrylic acid.

Such ionomers may comprise from 8 wt % to 25 wt % of an ethylenically unsaturated, C3 to C8 carboxylic acid, and may optionally comprise from 10 wt % to 20 wt % of an alkyl acrylate, based on the total weight of the ionomer.

Suitable ionomers and blends of a first ionomer and a second ionomer are further described in European patent EP1781735, which is hereby incorporated by reference.

In the case where the front encapsulant layer comprises a blend of a first ionomer and a non-neutralized copolymer of ethylene and (meth)acrylic acid, the non-neutralized copolymer of ethylene and (meth)acrylic acid preferably comprises from 2 to 15 weight percent, more preferably from 2 to 9 weight percent of (meth)acrylic acid, based on the total weight of the non-neutralized copolymer of ethylene and (meth)acrylic acid.

The front encapsulant layer can include more than one layer of encapsulant material, wherein each layer may include the same or an encapsulant material different from the other layer(s).

The front encapsulant layer may further comprise UV stabilization additives to prevent UV degradation of the encapsulant, but such additives are preferably not included in the front encapsulant layer in order to allow as much light as possible to go through the encapsulant layer.

The photovoltaic module according to the invention comprises one or more photovoltaic cells. With regard to the one or more photovoltaic cells comprising in the photovoltaic module of the present invention, reference is made to the definition of the term “photoactive cell” given above. The one or more photovoltaic cells may be connected together in series or in parallel to form an array of photovoltaic cells.

The photovoltaic module according to the invention comprises a back encapsulant layer having an area (A). The back encapsulant layer having an area (A) in the photovoltaic module according to the present invention is designed to encapsulate and further protect the one or more photoactive cells, and the back encapsulant layer also bonds the one or more photoactive cell to the back sheet.

The back encapsulant layer having an area (A) may comprise any suitable material known as encapsulant in the art of photovoltaic modules, and preferably has a Young modulus of from 1 to 200 MPa, more preferably of from 5 to 100 MPa, and most preferably of from 5 to 50 MPa, when measured according to ASTM D5026 at a temperature of 23° C. at a relative humidity of 23%.

The back encapsulant layer having an area (A) can include more than one layer of encapsulant material, wherein each layer may include the same or an encapsulant material different from the other layer(s).

Preferably, the back encapsulant layer having an area (A) in the module of the present invention comprises at least one of ethylene vinyl acetate copolymer, polyvinyl butyral, ethylene alkyl (meth)acrylate copolymer and thermoplastic polyurethane, and/or any combinations thereof.

The thickness of the back encapsulant layer may be in the range of, for example, 100 to 2000 μm, preferably of from 200 to 1000 μm, as is conventional for back encapsulant layers in photovoltaic modules.

The back sheet in the photovoltaic module according to the present invention may be any back sheet as is conventional in the art of photovoltaic modules, i.e. the back sheet may be formed from any rigid material, and the thickness of the back sheet may be in the range of, for example, 500 μm to 2 cm, as is conventional for back sheets of photovoltaic modules.

The function of the back sheet is to provide an electrically insulating layer that will reduce the risk of electrical shock in an operating photovoltaic module. The back sheet can be made of a rigid material, such as a glass, polyamide, polycarbonate, polyethylene terephthalate, epoxy resin, acrylate polymer such as polymethylmethacrylate (PMMA), glass fiber reinforced polymer such as any kind of glass fiber reinforced polyamide, carbon fiber reinforced polymer such as any kind of carbon fiber reinforced polyamide like polyamide 34, 6, 66, 6.66, 6T, 610, 10, 11, 12, glass reinforced polyester such as PET, PEN, PETG, asbestos, and ceramic.

In general, the back sheet material may be any material that provides electrical insulation and electrical shock protection. The back sheet may be a single layer of material, or may include more than one layer of material. In the case where the back sheet of the module includes more than one layer of material, it preferably includes a laminate consisting of one or more layers of polyethylene terephthalate sandwiched between polyvinyl fluoride (PVF) layers.

Preferably, the back sheet in the photovoltaic module according to the present invention has an area (A).

The present invention further provides for a process for the manufacture of a photovoltaic module comprising the steps of (a) assembling a stack by placing at least one sheet of a back encapsulant having an area (A) on top of a back sheet to form a back encapsulant layer thereon, placing one or more photoactive cells on top of the at least one sheet of the back encapsulant, placing one or more sheets of a front encapsulant consisting of one or more in-plane elements, on top of the one or more photoactive cells to form thereon a front encapsulant layer having a total area (B), placing a front sheet on top of the one or more front encapsulant sheets, and (b) consolidating the so assembled stack in a laminating device by heating the stack to a temperature of 100 to 180° C., subjecting the heated stack to a mechanical pressure in a direction perpendicular to the plane of the stack by forming a vacuum in the laminating device, cooling the stack to ambient temperature, and releasing the mechanical pressure by reestablishing atmospheric pressure in the laminating device, wherein the front encapsulant layer having the total area (B) covers the area defined by the one or more photovoltaic cells plus, optionally, the area between the photoactive cells, wherein the total area (B) of the front encapsulant layer formed is smaller than the area (A) of the back encapsulant layer, and wherein the contours of the one or more in-plane elements and the contour of the back encapsulant layer do not intersect.

In the process for manufacturing the photovoltaic module according to the present invention, the one or more elements of the front encapsulant layer may be cut or punched from sheets of front encapsulant or may be manufactured directly to the desired area or shape to match that of the one or more photovoltaic cells, plus, optionally that of the area between the photoactive cells, prior to the assembly of the stack.

In the process for manufacturing the photovoltaic module according to the present invention, the step of assembling a stack by placing the components of the photovoltaic module according to the above process may be carried out manually or automatically.

In the process for manufacturing the photovoltaic module according to the present invention, the step of assembling a stack may be carried out outside or inside a laminating device, and is preferably directly carried out inside a laminating device, so as to reduce production cycle times. A laminating device useful in the process for manufacturing the photovoltaic module can be a vacuum heat press, for example.

In the process for manufacturing the photovoltaic module, the heating of the stack in the laminating device can be achieved by heating the top, lower, or even both platen of the laminating device. The assembled stack is then heated to a temperature of, for example, 100 to 180° C., in particular to 120 to 170° C. and more particularly to 130 to 150° C.

The heating of the stack allows the encapsulants to soften, flow and adhere to the photovoltaic cells, thereby consolidating the stack of components into the photovoltaic module according to the present invention.

In the process for manufacturing the photovoltaic module, the mechanical pressure perpendicular to the plane of the heated stack may be exerted via the platen of the laminating device by forming a vacuum in the laminating device of, for example, 1 to 1000 mbar, in particular 1 to 550 mbar and more particularly 1 to 250 mbar. Forming a vacuum in the laminating device further facilitates the removal of air pockets trapped between the different layers of the stack.

The consolidation step of the process for manufacturing the photovoltaic module ends with the cooling of the stack to ambient temperature and the release of the mechanical pressure by reestablishing atmospheric pressure in the laminating device.

### EXAMPLES

### Comparative Example 1

A sheet of ethylene vinyl acetate copolymer (EVA) back encapsulant, commercially available from Etimex (Dietenheim, DE) under the trademark VISTASOLAR (Type 486.10), having a thickness of 450 micron and dimensions of 1 m×1.4 m, was superposed on a sheet of polyvinyl fluoride/polyethylene terephthalate/polyvinyl fluoride (TPT™) back sheet, commercially available from Isovoltaic (Lebring, AT) under the trademark Icosolar® 2442 having dimensions of 1 m×1.4 m.

Two crystalline silicon photovoltaic cells were then placed on top of the sheet of EVA at the center of the sheet.

A sheet of ionomer front encapsulant, commercially available from E.I. du Pont de Nemours and Company (Wilmington, US) under the trademark PV5316 NC, having a thickness of 890 micron and dimensions of 1 m×1.4 m was superposed on the photovoltaic cells so as to cover the photovoltaic cells and so as to completely cover the back encapsulant.

A sheet of annealed glass having the dimensions of 1 m×1.4 m was then superposed on the front sheet of ionomer front encapsulant. The resulting stack having the following structure from bottom to top, TPT/EVA/cells/ionomer/glass, was inserted into a 3S laminating machine for consolidation by lamination.

The lamination was performed at a temperature of 155° C. and an internal lamination pressure of 990 mbar in the laminating machine for an overall time of 10 minutes.

### Example 2

A photovoltaic module was manufactured according to the procedure described under Example 1, with the difference that the sheet of ionomer front encapsulant had dimensions of 0.95 m×1.30 m and was superposed on the photovoltaic cells so as to cover the photovoltaic cells and so as to only partially cover the back encapsulant, and was centered so as to leave an ionomer-free border of 5 cm and, respectively, 2.5 cm on the edges of the module.

### Results

The thus obtained photovoltaic module was subsequently subjected to a damp heat test according to IEC61215:2005 Section 10.13. The modules were inserted in to a climate chamber operating at 85° C. and 85% relative humidity and were visually inspected for delamination defects after 100, 1000 and 1500 hours in the climate chamber. Results are shown in Table 1.

Table 1 shows the results from visual inspection of photovoltaic modules according to example 1 and 2 after going through 100, 1000, and 1500 hours of exposure in a climate chamber at 85° C. and 85% relative humidity.

TABLE 1

| | 100 hours | 1000 hours | 1500 hours |
|---|---|---|---|
| Comparative | Delamination | ** | ** |
| Example 1 | defects | | |
| Example 2 | Intact | Intact | Intact |

** Exposure discontinued when delamination was observed

As can be seen from the results shown in Table 1, the photovoltaic module of Example 2 where the area of the front encapsulant layer is smaller than the area of the back encapsulant layer shows no delamination defects when subjected to a 100, 1000 and 1500 hours of damp heat according to the IEC31215:2005 Section 10.13 procedure. In contrast, photovoltaic modules where the front encapsulant layer has the same area as the back encapsulant layer already show dramatic delamination defects after only 100 hours in damp heat.

The photovoltaic module according to the present invention is therefore superior in lifetime, especially in tropical climates, when compared to a conventional photovoltaic module.

What is claimed is:

1. A photovoltaic module comprising, in this order:
i. a front sheet;
ii. a front encapsulant layer having a total area (B), consisting of one or more in-plane elements, each of said one or more in plane elements of said front encapsulant layer having a contour;
iii. one or more photoactive cells;
iv. a back encapsulant layer having an area (A), said back encapsulant layer having a contour; and
v. a back sheet;
wherein the front encapsulant layer having the total area (B) covers the area defined by the one or more photovoltaic cells and wherein the total area (B) of the front encapsulant layer is smaller than the area (A) of the back encapsulant layer, and wherein the contours of the one or more in-plane elements of the front encapsulant layer and the contour of the back encapsulant layer do not intersect.

2. The photovoltaic module according to claim 1, wherein the front encapsulant layer having the total area (B) only covers the area defined by the one or more photovoltaic cells plus the area between the photoactive cells.

3. The photovoltaic module according to claim 1, wherein the front encapsulant layer having the total area (B) only covers the area defined by the one or more photovoltaic cells.

4. The photovoltaic module according to claim 1, wherein the front encapsulant layer comprises at least one polymer having a Young Modulus of from 200 to 400 MPa, when measured according to ASTM D5026 at 23° C. and 23% relative humidity.

5. The photovoltaic module according to claim 4, wherein the at least one polymer comprising said front encapsulant layer is a first ionomer.

6. The photovoltaic module according to claim 5, wherein the front encapsulant layer comprises a blend of the first ionomer and a second ionomer different from the first ionomer or a blend of the first ionomer and an non-neutralized copolymer of ethylene and (meth)acrylic acid.

7. The photovoltaic module according to claim 4, wherein the back encapsulant layer comprises at least one polymer having a Young Modulus of from 1 to 200 MPa, when measured according to ASTM D5026 at 23° C. and 23% relative humidity.

8. The photovoltaic module according to claim 7 wherein the back encapsulant layer comprises at least one of ethylene vinyl acetate copolymer, polyvinyl butyral, ethylene alkyl (meth)acrylate copolymer and thermoplastic polyurethane, and any combinations thereof.

9. The photovoltaic module according to claim 1, wherein the front sheet has the same area (A) as the back encapsulant layer.

10. The photovoltaic module according to claim 1 wherein said front encapsulant layer and said back encapsulant layer are each adhered directly to the front sheet.

11. A process for the manufacture of a photovoltaic module comprising the steps of:
(a) assembling a stack by
i. placing at least one sheet of a back encapsulant having an area (A) on top of a back sheet to form a back encapsulant layer thereon, said back encapsulant layer having a contour,
ii. placing one or more photoactive cells on top of the at least one sheet of the back encapsulant,
iii. placing one or more sheets of a front encapsulant consisting of one or more in-plane elements on top of the one or more photoactive cells to form thereon a front encapsulant layer having a total area (B), each of said one or more sheets of front encapsulant of said front encapsulant layer having a contour,
iv. placing a front sheet on top of the one or more front encapsulant sheets; and
(b) consolidating the so assembled stack in a laminating device by
i. heating the stack to a temperature of 100 to 180° C.,
ii. subjecting the heated stack to a mechanical pressure in a direction perpendicular to the plane of the stack by forming a vacuum in the laminating device,
iii. cooling the stack to ambient temperature, and
iv. releasing the mechanical pressure by reestablishing atmospheric pressure in the laminating device;
wherein the front encapsulant layer having the total area (B) covers the area defined by the one or more photovoltaic cells, and wherein the total area (B) of the front encapsulant layer is smaller than the area (A) of the back encapsulant layer, and wherein the contours of the one or more front encapsulant sheet of the front encapsulant layer and the contour of the back encapsulant layer do not intersect.

12. The process for the manufacture of a photovoltaic module according to claim 11, wherein the front encapsulant layer having the total area (B) covers only the area defined by the one or more photovoltaic cells plus the area between the photoactive cells.

13. The process for the manufacture of a photovoltaic module according to claim 11, wherein the front encapsulant layer having the total area (B) covers only the area defined by the one or more photovoltaic cells.

14. The process for the manufacture of a photovoltaic module according to claim 11, wherein the front encapsulant layer comprises at least one polymer having a Young Modulus of from 200 to 400 MPa, when measured according to ASTM D5026 at 23° C. and 23% relative humidity.

15. The process for the manufacture of a photovoltaic module according to claim 14, wherein the at least one polymer comprising said front encapsulant layer is a first ionomer.

16. The process for the manufacture of a photovoltaic module according to claim 14, wherein the back encapsulant layer comprises at least one polymer having a Young Modulus of from 1 to 200 MPa, when measured according to ASTM D5026 at 23° C. and 23% relative humidity.

17. The process for the manufacture of a photovoltaic module according to claim 16, wherein the back encapsulant layer comprises at least one of ethylene vinyl acetate copolymer, polyvinyl butyral, ethylene alkyl (meth)acrylate copolymer and thermoplastic polyurethane, and any combinations thereof.

18. The process for the manufacture of a photovoltaic module according to claim 11, wherein said front encapsulant layer and said back encapsulant layer are each adhered directly to the front sheet.
